(19) United States
(12) Patent Application Publication
(10) Pub. No.: US 2025/0151606 A1
(43) Pub. Date: May 8, 2025

(54) DISPLAY DEVICE AND LIGHT EMITTING COMPONENT

(71) Applicant: BOE Technology Group Co., Ltd., Beijing (CN)

(72) Inventors: Yang LIU, Beijing (CN); Dan WANG, Beijing (CN); Lei CHEN, Beijing (CN)

(21) Appl. No.: 18/693,943

(22) PCT Filed: Feb. 24, 2023
(86) PCT No.: PCT/CN2023/078218

§ 371 Date: Mar. 20, 2024

(51) Int. Cl. H10K 85/30; C09K 11/02; H10K 50/12; H10K 85/60

(52) U.S. Cl. CPC H10K 85/342; C09K 11/02; H10K 50/12; H10K 85/633; H10K 85/654; H10K 85/6572; H10K 85/6574; H10K 85/6576

(57) ABSTRACT

The present disclosure provides a display device and a light emitting component. The light emitting component includes: an anode and a cathode arranged oppositely; a light emitting layer between the anode and the cathode, where the light emitting layer includes a host material and a dopant material, the host material includes hole type material and electron type material, the electron transport rate exceeds the hole transport rate in the light emitting layer; and an electron barrier layer on a surface of the light emitting layer facing the anode; where the hole type material, the electron type material, the dopant material, and the electron barrier layer or any combination thereof includes a deuterium-substituted compound.

### TECHNICAL FIELD

The present disclosure relates to the field of display technology, and in particular, to a display device and a light emitting component.

### BACKGROUND

With the improvement of living standards, OLED (Organic Light Emitting Diode) light emitting components have attracted more and more attention. OLED light emitting components have a series of advantages such as an all-solid-state structure, self-illumination, rapid response times, high brightness, full viewing angles, and flexible displays, etc. However, the lifespan of current light emitting components is relatively low.

### SUMMARY

The purpose of the present disclosure is to provide a display device and a light emitting component, which can improve the lifespan of the light emitting component.

According to an aspect of the disclosure, there is provided a light emitting component, including:
an anode and a cathode arranged oppositely;
a light emitting layer between the anode and the cathode, where the light emitting layer includes a host material and a dopant material, the host material includes a hole type material and an electron type material;
an electron barrier layer on a surface of the light emitting layer facing the anode; and
the hole type material, the electron type material, the dopant material, the electron barrier layer or any combination thereof includes a deuterium-substituted compound;
where the dopant material includes a compound having a structural formula as shown in Formula 1:

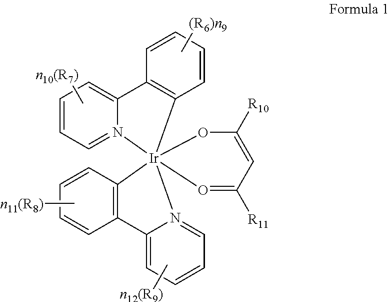

where R₆-R₉ are each independently selected from a group consisting of hydrogen and deuterium; where R₆-R₉ are further each independently selected from a group consisting of methyl, ethyl, propyl, cyclohexyl, and phenyl that are deuterium-substituted or non-deuterium-substituted;
where n₉-n₁₂ are each independently 0, 1, 2, 3, or 4;
where R₁₀ and R₁₁ are each independently selected from a group consisting of deuterium-substituted methyl, deuterium-substituted ethyl, and deuterium-substituted propyl or non-deuterium-substituted.

Further, the hole type material includes a compound having a structural formula as shown in Formula 2:

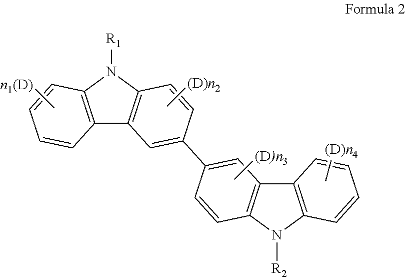

where, R₁ and R₂ are each independently selected from a group consisting of benzene, biphenyl, terphenyl, naphthalene, dibenzofuran, dibenzothiophene, dimethylfluorene, and diphenylfluorene that are deuterium-substituted or non-deuterium-substituted;
n₁ and n₄ are each independently 0, 1, 2, 3, or 4; n₂ and n₃ are each independently 0, 1, 2, or 3.

Further, R₁-R₂ are each independently selected from a group consisting of

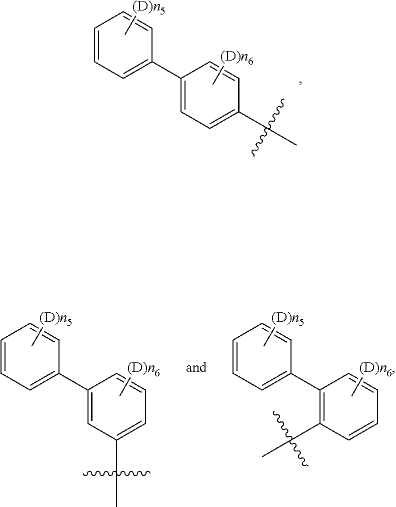

where, n₅ is 0, 1, 2, 3, 4, or 5; n₆ is 0, 1, 2, 3, or 4.

Further, the hole type material includes a compound having any one of the following structural formulas:

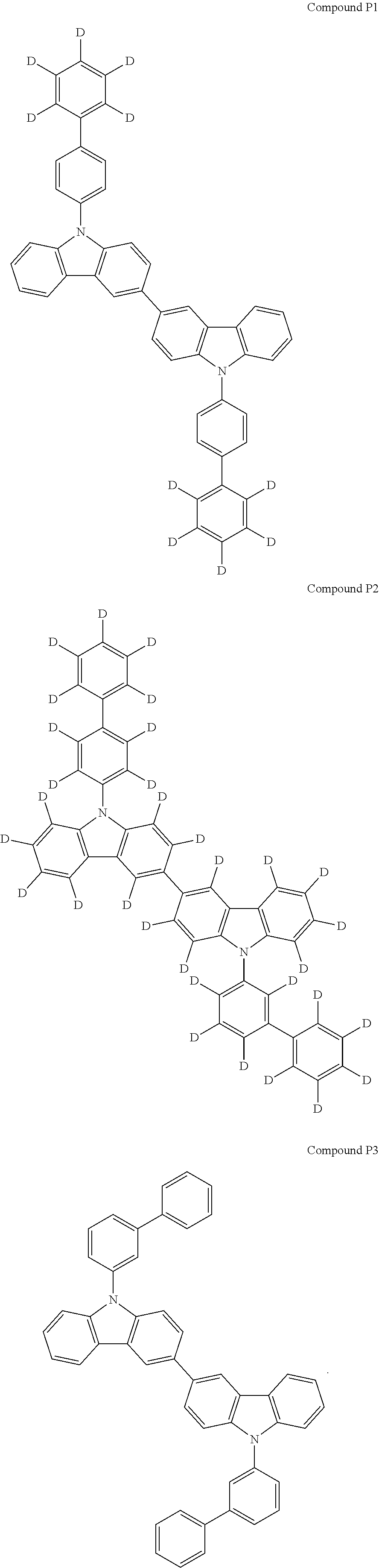 [SMILES: [2H]c1c([2H])c([2H])c(-c2ccc(-n3c4ccccc4c4cc(-c5ccc6c(c5)c5ccccc5n6-c5ccc(-c6c([2H])c([2H])c([2H])c([2H])c6[2H])cc5)ccc43)cc2)c([2H])c1[2H] ; [2H]c1c([2H])c([2H])c(-c2c([2H])c([2H])c(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])c([2H])c([2H])c(-c6c([2H])c([2H])c([2H])c([2H])c6[2H])c5[2H])c([2H])c([2H])c43)c([2H])c2[2H])c([2H])c1[2H] ; c1ccc(-c2cccc(-n3c4ccccc4c4cc(-c5ccc6c(c5)c5ccccc5n6-c5cccc(-c6ccccc6)c5)ccc43)c2)cc1]

Further, a quantity of deuterium atoms in the compound having the structural formula as shown in Formula 2 is less than or equal to 32.

Further, the electron type material includes a compound having a structural formula as shown in Formula 3:

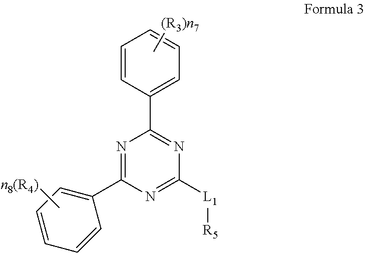

where, R₃ and R₄ are each independently selected from a group consisting of hydrogen and deuterium, and R₃ and R₄ are further each independently selected from a group consisting of benzene, biphenyl, naphthalene, dibenzofuran, and dibenzothiophene that are deuterium-substituted or non-deuterium-substituted;
n₇ and n₈ are each independently 0, 1, 2, 3, 4, and 5;
R₅ and L₁ are each independently selected from a group consisting of benzene, biphenyl, naphthalene, dibenzofuran, dibenzothiophene, and carbazole that are deuterium-substituted or non-deuterium-substituted.

Further, R₃ and R₄ are each independently

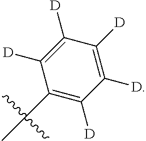

Further, R₅ is

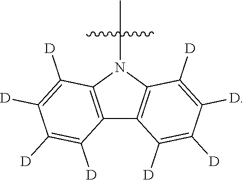

Further, L₁ is

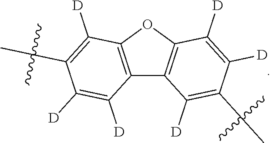 [SMILES: *c1c([2H])c([2H])c2c(oc3c([2H])c([2H])c(*)c([2H])c32)c1[2H]]

Further, the electron type material includes a compound having any one of the following structural formulas:

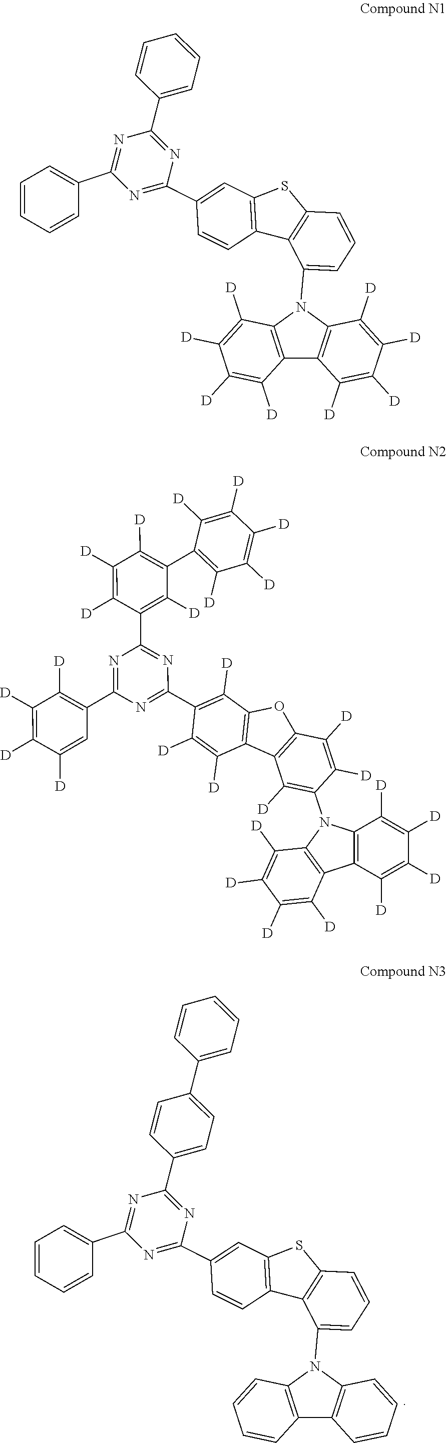 [SMILES: [2H]c1c([2H])c([2H])c2c(c1[2H])c1c([2H])c([2H])c([2H])c([2H])c1n2-c1cccc2sc3cc(-c4nc(-c5ccccc5)nc(-c5ccccc5)n4)ccc3c12 ; [2H]c1cc(-c2nc(-c3c([2H])c([2H])c([2H])c(-c4c([2H])c([2H])c([2H])c([2H])c4[2H])c3[2H])nc(-c3c([2H])c([2H])c4c(oc5c([2H])c([2H])c(-n6c7c([2H])c([2H])c([2H])c([2H])c7c7c([2H])c([2H])c([2H])c([2H])c76)c([2H])c54)c3[2H])n2)c([2H])c([2H])c1[2H] ; c1ccc(-c2ccc(-c3nc(-c4ccccc4)nc(-c4ccc5c(c4)sc4cccc(-n6c7ccccc7c7ccccc76)c45)n3)cc2)cc1]

Further, a quantity of deuterium atoms in the compound having the structural formula as shown in Formula 3 is less than or equal to 38.

Further, R₆-R₁₁ are each independently

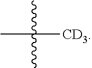 [SMILES: *C([2H])([2H])[2H]]

Further, the dopant material includes a compound having any one of the following structural formulas:

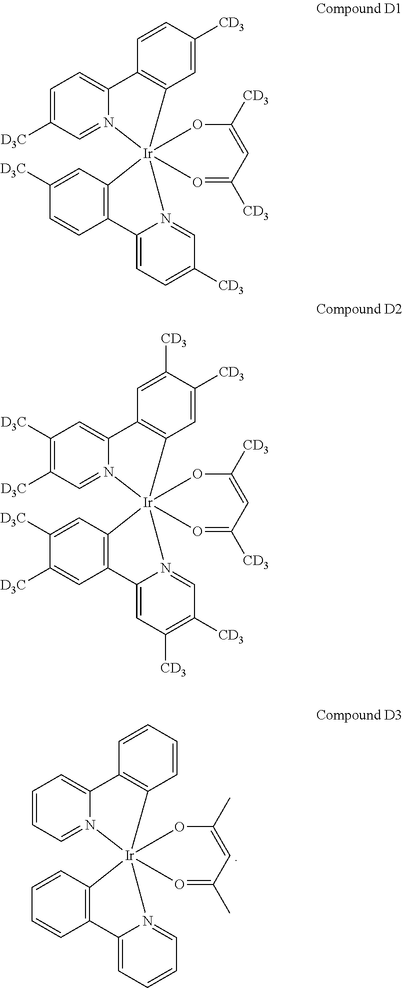

Further, a quantity of deuterium atoms in the compound having the structural formula as shown in Formula 1 is less than or equal to 32; and/or
the quantity of deuterium atoms in the compound having the structural formula as shown in Formula 1 is greater than or equal to 3.

Further, R₁₀ and R₁₁ are each independently selected from a group consisting of deuterium-substituted methyl, deuterium-substituted ethyl, and deuterium-substituted propyl.
a ratio of the quantity of deuterium atoms in R₁₀ and R₁₁ to the quantity of deuterium atoms in the compound having the structural formula as shown in Formula 1 is greater than or equal to 1/11; and/or, the ratio of the quantity of deuterium atoms in R₁₀ and R₁₁ to the quantity of deuterium atoms in the compound having the structural formula as shown in Formula 1 is less than or equal to 1/3.

Further, the dopant material is a phosphorescent material;
an orientation value of the dopant material in the light emitting layer is greater than or equal to −0.45; and/or, the orientation value of the dopant material in the light emitting layer is less than or equal to −0.15.

Further, the electron barrier layer includes a compound having a structural formula as shown in Formula 4:

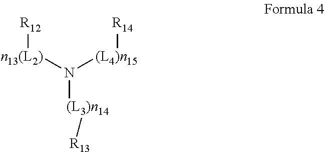

where, R₁₂, R₁₃, R₁₄, L₂, L₃, and L₄ are each independently selected from a group consisting of benzene, biphenyl, naphthalene, dibenzofuran, dibenzothiophene, dimethylfluorene, diphenylfluorene, spirofluorene, carbazole, and adamantine that are deuterium-substituted or non-deuterium-substituted;
n₁₃, n₁₄, and n₁₅ are each independently 0 or 1.

Further, R₁₂, R₁₃, and R₁₄ are each independently selected from a group consisting of

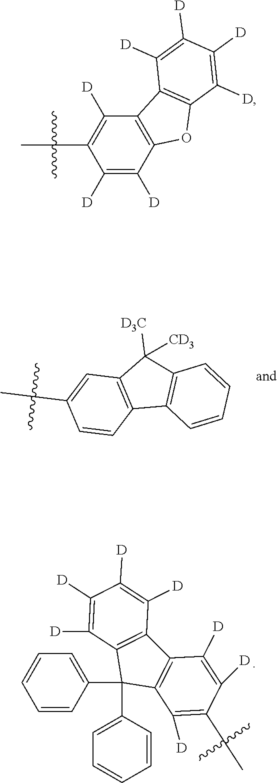

Further, the electron barrier layer includes a compound having any one of the following structural formulas:

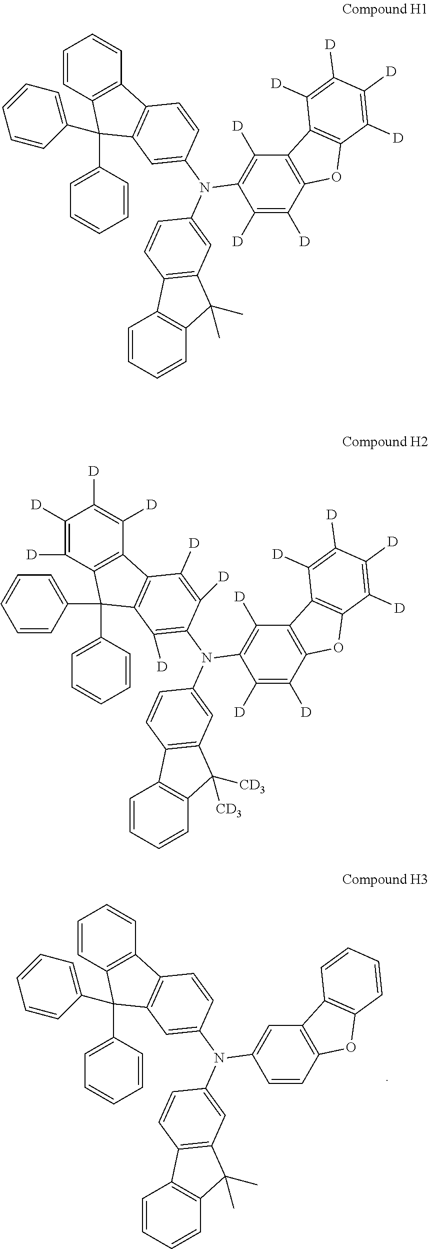 [SMILES: [2H]c1c([2H])c([2H])c2c(oc3c([2H])c([2H])c(N(c4ccc5c(c4)C(C)(C)c4ccccc4-5)c4ccc5c(c4)C(c4ccccc4)(c4ccccc4)c4ccccc4-5)c([2H])c32)c1[2H] ; [2H]c1c([2H])c([2H])c2c(c1[2H])-c1c([2H])c([2H])c(N(c3ccc4c(c3)C(C([2H])([2H])[2H])(C([2H])([2H])[2H])c3ccccc3-4)c3c([2H])c([2H])c4oc5c([2H])c([2H])c([2H])c([2H])c5c4c3[2H])c([2H])c1C2(c1ccccc1)c1ccccc1 ; CC1(C)c2ccccc2-c2ccc(N(c3ccc4c(c3)C(c3ccccc3)(c3ccccc3)c3ccccc3-4)c3ccc4oc5ccccc5c4c3)cc21]

Further, a quantity of deuterium atoms in the compound having the structural formula as shown in Formula 4 is less than or equal to 30.

Further, a quantity of deuterium atoms in the hole type material, the electron type material, the dopant material, and the electron barrier layer is less than or equal to 108; and/or
the quantity of deuterium atoms in the hole type material, the electron type material, the dopant material, and the electron barrier layer is greater than or equal to 4.

According to an aspect of the present disclosure, there is provided a display device including the light emitting component.

The display device and the light emitting component of the present disclosure have a host material including a hole type material and an electron type material. An electron barrier layer is on a surface of the light emitting layer facing the anode. Since the hole type material, the electron type material, the dopant material, the electron barrier layer or any combination thereof includes a deuterium-substituted compound, it is difficult for the part of the light emitting layer in the exciton recombination region and the part of the electron barrier layer close to the exciton recombination region to crack, which can improve the component lifespan.

### BRIEF DESCRIPTION OF DRAWINGS

FIG. 1 is a schematic diagram of charge carrier transport in the related art.

FIG. 2 is a schematic diagram of a light emitting component according to an embodiment of the present disclosure.

The reference numerals indicate: 1, an anode; 2, a hole injection layer; 3, a hole transport layer; 4, an electron barrier layer; 5, a light emitting layer; 51, an exciton recombination region; 6, a hole barrier layer; 7, an electron transport layer; 8, an electron injection layer; 9, a cathode.

### DETAILED DESCRIPTION

Exemplary embodiments will be described in detail here, examples of which are illustrated in the accompanying drawings. When the following description relates to the accompanying drawings, unless specified otherwise, the same numerals in different drawings represent the same or similar elements. The implementations described in the following examples do not represent all implementations consistent with the present disclosure. Conversely, they are merely device examples consistent with some aspects of the present disclosure as detailed in the appended claims.

The terms used in the present disclosure is for the purpose of describing a particular example only, and is not intended to be limiting of the present disclosure. Unless otherwise defined, the technical or scientific terms used in the present disclosure shall have the usual meanings understood by those of ordinary skill in the field to which the present disclosure belongs. It is to be understood that, “first”, “second” and similar terms used in the specification and the claims of the present application do not indicate any sequence or importance, but are only used to distinguish different components. Similarly, “one”, “a”, and similar terms also do not indicate a quantity limitation, but indicates that there is at least one. The term “a plurality” indicates two or more, unless specifically defined otherwise. Unless otherwise stated, the terms such as “front”, “rear”, “lower”, and/or “upper” are for ease of description only and are not limited to a position or a spatial orientation. The terms such as “comprise”, “include”, or any variant thereof mean that an element or article preceded by “comprise” or “include” encompasses elements or articles and their equivalents listed after “comprise” or “include”, do not exclude the existence of other elements or articles. “Connected to” or “connected with” and similar terms are not limited to physical or mechanical connections, and can include electrical connections, whether direct or indirect. Terms like “a”, “the” and “said” in their singular forms in the present disclosure and the appended claims are also intended to include plurality, unless clearly indicated otherwise in the context. It should also be understood that the term “and/or” used herein includes any and all possible combinations of one or more of the associated listed items.

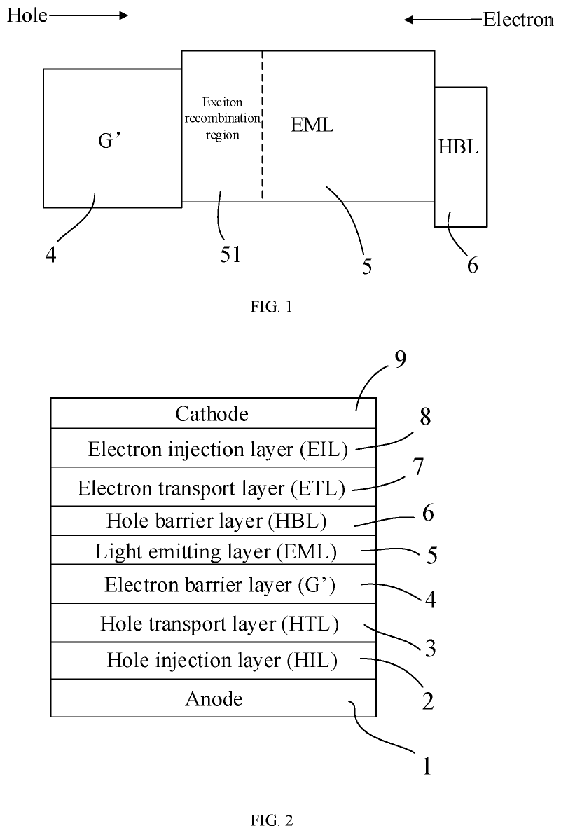

In the related art, OLED light emitting components capable of emitting green light belong to phosphorescent components. As illustrated in FIG. 1, the light emitting component includes a light emitting layer (emitting layer, EML) 5, the light emitting layer 5 includes a host material and a guest material. Charge carriers include holes and electrons, electrons are transported to the light emitting layer 5 through a hole barrier layer 6 (HBL), and holes are transported to the light emitting layer 5 through an electron barrier layer 4 (G′). In the light emitting layer 5, since the electron transport rate is much greater than the hole transport rate, resulting in the exciton recombination region 51 being relatively concentrated and on a side of the light emitting layer 5 close to the electron barrier layer 4, consequently, the part of the light emitting layer 5 in the exciton recombination region 51 and the part of the electron barrier layer 4 close to the exciton recombination region 51 are prone to crack, reducing the lifespan of the light emitting component.

A light emitting component is provided according to embodiments of the present disclosure. As illustrated in FIG. 2, the light emitting component may include an anode 1, a cathode 9, a light emitting layer 5, and an electron barrier layer 4, where:
the anode 1 and the cathode 9 are at opposite sides of the light-emitting component. The light emitting layer 5 (EML) is between the anode 1 and the cathode 9. The light emitting layer 5 includes a host material and a dopant material. The host material includes a hole type material and an electron type material. The electron transport rate in the light emitting layer 5 exceeds the hole transport rate in the light emitting layer. The electron-barrier layer 4 (G′) is on a surface of the light emitting layer 5 facing the anode 1. At least one of the hole type material, the electron type material, the dopant material, or the electron barrier layer 4 includes a deuterium-substituted compound.

The aforementioned dopant material includes a compound having a structural formula as shown in Formula 1:

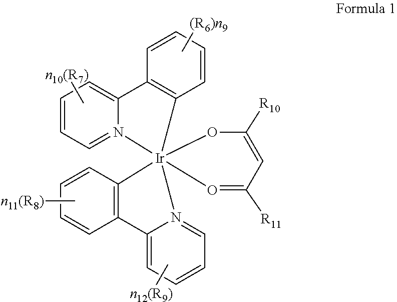

where, R₆-R₉ are each independently selected from a group consisting of hydrogen and deuterium; R₆-R₉ are further each independently selected from a group consisting of methyl, ethyl, propyl, cyclohexyl, and phenyl that are deuterium-substituted or non-deuterium-substituted; n₉-n₁₂ are each independently 0, 1, 2, 3, or 4; R₁₀ and R₁₁ are each independently selected from a group consisting of deuterium-substituted methyl, deuterium-substituted ethyl, and deuterium-substituted propyl or non-deuterium-substituted.

In the light emitting component according to embodiments of the present disclosure, the host material includes a hole type material and an electron type material. The electron barrier layer 4 is on the surface of the light emitting layer 5 facing the anode 1, and the electron transport rate in the light emitting layer 5 exceeds the hole transport rate in the light emitting layer. Since the hole type material, the electron type material, the dopant material, the electron barrier layer 4 or any combination thereof includes a deuterium-substituted compound, it is difficult for the part of the light emitting layer 5 in the exciton recombination region 51 and the part of the electron barrier layer 4 close to the exciton recombination region 51 to crack, which can improve the component lifespan.

The following provides a detailed description of the light emitting component according to embodiments of the present disclosure:

The anode 1 may include materials having high work function. Specific examples of anode 1 materials include: metals such as nickel, platinum, vanadium, chromium, copper, zinc, and gold, or their alloys; metal oxides such as zinc oxide, indium oxide, indium tin oxide (ITO), and indium zinc oxide (IZO); combinations of metals and oxides such as ZnO:Al or SnO₂:Sb; or conductive polymers such as poly(3-methylthiophene), poly [3,4-(Ethylene-1,2-dioxy)thiophene] (PEDT), polypyrrole, and polyaniline, but the present disclosure is not limited thereto. In some embodiments, indium tin oxide is used as the anode 1.

The cathode 9 may include materials having low work function. Specific examples of cathode 9 materials include: metals such as magnesium, calcium, sodium, potassium, titanium, indium, yttrium, lithium, gadolinium, aluminum, silver, tin, and lead, or their alloys; or multilayer materials such as LiF/Al, Liq/Al, LiO₂/Al, LiF/Ca, LiF/Al, and BaF₂/Ca, but are not limited thereto. In some embodiments, a metal electrode including an Mg—Ag alloy is used as the cathode 9.

The light emitting layer 5 is between the anode 1 and the cathode 9. The light emitting layer 5 includes a host material and a dopant material. The host material includes a hole type material and an electron type material. The hole type material is a P-type material, and the electron type material is an N-type material. Under the influence of external energy, the host material is configured to be capable of forming exciplexes.

The hole type material may include a compound having a structural formula as shown in Formula 2:

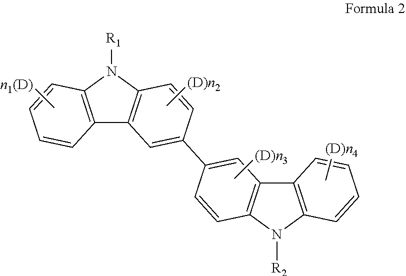

where, R₁ and R₂ are each independently selected from a group consisting of benzene, biphenyl, terphenyl, naphthalene, dibenzofuran, dibenzothiophene, dimethylfluorene, and diphenylfluorene that are deuterium-substituted or non-deuterium-substituted; the “D” in the compound represents deuterium, also referred to as heavy hydrogen. n₁ and n₄ are each independently 0, 1, 2, 3, or 4; n₂ and n₃ are each independently 0, 1, 2, or 3. At least one of n₁, n₂, n₃, or n₄ is not 0, but the present disclosure does not specifically limit this. The hole type material contains a carbazole structure, which can increase hole injection and improve the hole electron balance, thereby improving efficiency and component lifespan.

Further, R₁-R₂ are each independently selected from a group consisting of

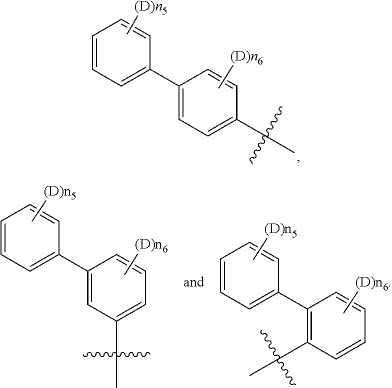

“ [symbol] ” represents a linking bond. n₅ is 0, 1, 2, 3, 4, or 5; n₆ is 0, 1, 2, 3, or 4. In addition, the aforementioned R₁ and R₂ may be the same as each other, or certainly, may be different from each other.

The quantity of deuterium atoms in the compound having the structural formula as shown in Formula 2 is less than or equal to 32, that is to say, the sum of n₁, n₂, n₃, n₄, n₅, and no is less than or equal to 32. The sum of n₁, n₂, n₃, n₄, n₅, and no may be greater than or equal to 0.

For example, the hole type material includes a compound having any one of the following structural formulas:

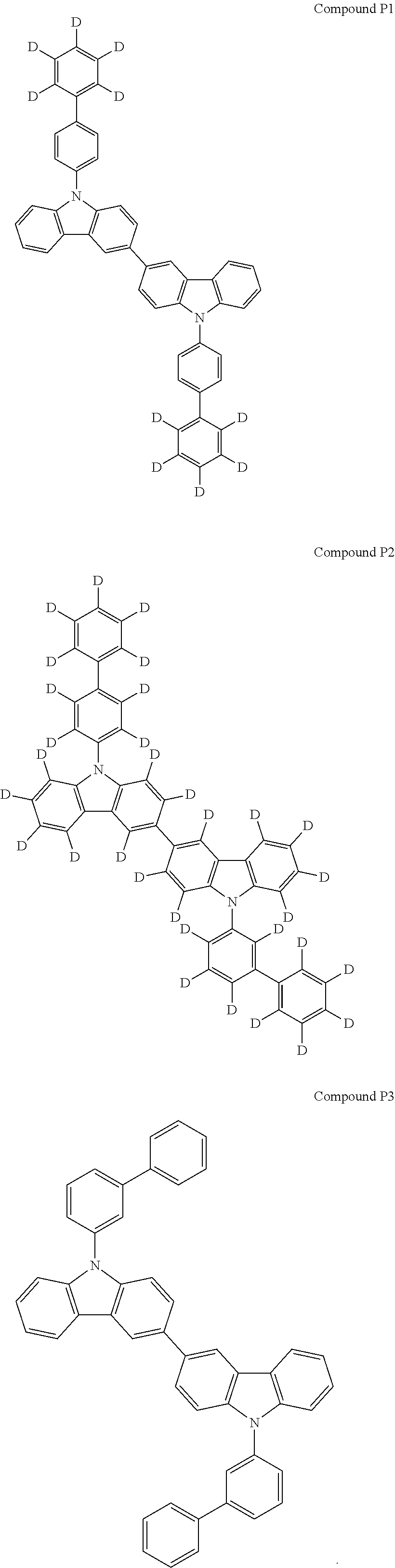 [SMILES: [2H]c1c([2H])c([2H])c(-c2ccc(-n3c4ccccc4c4cc(-c5ccc6c(c5)c5ccccc5n6-c5ccc(-c6c([2H])c([2H])c([2H])c([2H])c6[2H])cc5)ccc43)cc2)c([2H])c1[2H] ; [2H]c1c([2H])c([2H])c(-c2c([2H])c([2H])c(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])c([2H])c([2H])c(-c6c([2H])c([2H])c([2H])c([2H])c6[2H])c5[2H])c([2H])c([2H])c43)c([2H])c2[2H])c([2H])c1[2H] ; c1ccc(-c2cccc(-n3c4ccccc4c4cc(-c5ccc6c(c5)c5ccccc5n6-c5cccc(-c6ccccc6)c5)ccc43)c2)cc1]

The synthesis method of the above compound P1 includes follows:

### (1) Synthesis of Intermediate P1-1

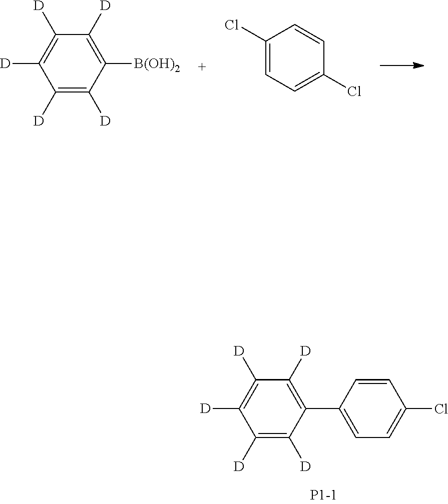 [SMILES: [2H]c1c([2H])c([2H])c(B(O)O)c([2H])c1[2H] ; Clc1ccc(Cl)cc1 ; [2H]c1c([2H])c([2H])c(-c2ccc(Cl)cc2)c([2H])c1[2H]]

Phenylboronic acid (6.2 g; 48.8 mmol), 1,4-dichlorobenzene (7.2 g; 48.8 mmol), tetrakis triphenylphosphine palladium (1.1 g; 1.0 mmol), potassium carbonate (13.5 g; 97.7 mmol), tetrabutylammonium bromide (3.1 g; 9.8 mmol), toluene (50 mL), ethanol (15 mL), and deionized water (15 mL) are added into a nitrogen-gas-protected round-bottomed flask, the temperature is raised to 75° C.-80° C., and the reaction is stirred for 12 hours; the reaction solution is lowered to room temperature, deionized water (100 mL) is added, and liquid separation is performed, after the organic phase is washed with water and dried with anhydrous magnesium sulfate, the solvent is removed under reduced pressure; the obtained crude product is purified by performing silica gel column chromatography purification via a dichloromethane/n-heptane solvent system to obtain a white solid, i.e., intermediate P1-1 (9.4 g; 81%).

### (2) Synthesis of Compound P1

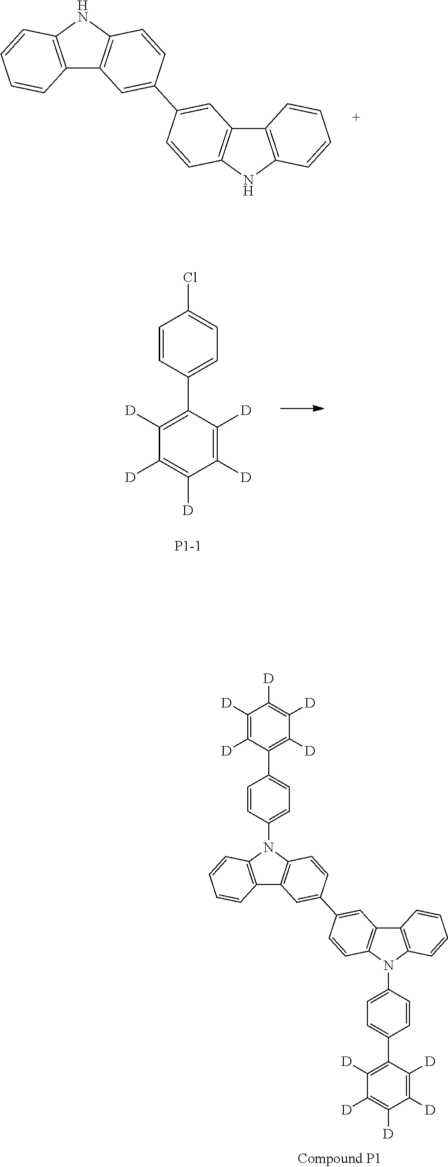 [SMILES: c1ccc2c(c1)[nH]c1ccc(-c3ccc4[nH]c5ccccc5c4c3)cc12 ; [2H]c1c([2H])c([2H])c(-c2ccc(Cl)cc2)c([2H])c1[2H] ; [2H]c1c([2H])c([2H])c(-c2ccc(-n3c4ccccc4c4cc(-c5ccc6c(c5)c5ccccc5n6-c5ccc(-c6c([2H])c([2H])c([2H])c([2H])c6[2H])cc5)ccc43)cc2)c([2H])c1[2H]]

3,3′-bicarbazole (6.2 g; 20.4 mmol), P1-1 (7.8 g; 40.8 mmol), tris(dibenzylideneacetone) dipalladium (0.18 g; 0.2 mmol), 2-dicyclohexylphosphine-2′6′-dimethoxy-biphenyl (0.17 g; 0.4 mmol), sodium tert-butoxide (2.9 g; 30.6 mmol) and xylene (100 mL) are added to the round-bottomed flask under nitrogen gas protection. The reaction is stirred at 135° C. for 16 hours; after being lowered to room temperature, the reaction solution is washed with water and separated, the organic phase is dried with anhydrous magnesium sulfate, and the solvent is removed under reduced pressure to obtain the crude product; the crude product is purified by performing silica gel column chromatography purification via dichloromethane/n-heptane used as eluent, the compound P1 (7.6 g, yield 78%) is obtained.

The aforementioned electron type material may include a compound having a structural formula as shown in Formula 3:

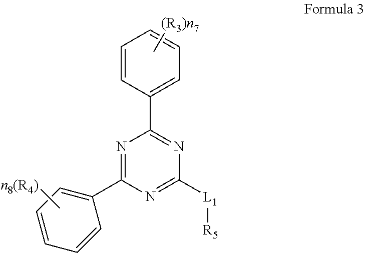

where, R₃ and R₄ are each independently selected from a group consisting of hydrogen and deuterium, and R₃ and R₄ are further each independently selected from a group consisting of benzene, biphenyl, naphthalene, dibenzofuran, and dibenzothiophene that are deuterium-substituted or non-deuterium-substituted. Further, the aforementioned R₃ and R₄ may each independently be

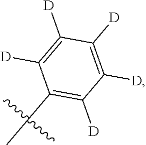

i.e., R₃ and R₄ may each independently be a benzene substituted by five deuterium atoms.
n₇ and n₈ are each independently 0, 1, 2, 3, 4, or 5.
R₅ is independently selected from a group consisting of benzene, biphenyl, naphthalene, dibenzofuran, dibenzothiophene, and carbazole that are deuterium-substituted or non-deuterium-substituted. Further, R₅ may be

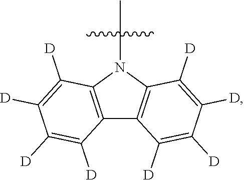

i.e., R₅ may be a carbazole substituted with eight deuterium atoms.
L₁ is independently selected from a group consisting of benzene, biphenyl, naphthalene, dibenzofuran, dibenzothiophene, and carbazole that are deuterium-substituted or non-deuterium-substituted. Further, L₁ may be

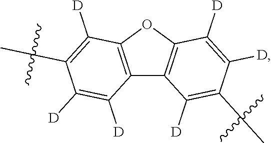

i.e., L₁ may be a dibenzofuran substituted by six deuterium atoms.

In addition, the quantity of deuterium atoms in the compound having the structural formula as shown in Formula 3 may be less than or equal to 38.

For example, the electron type material includes a compound having any one of the following structural formulas:

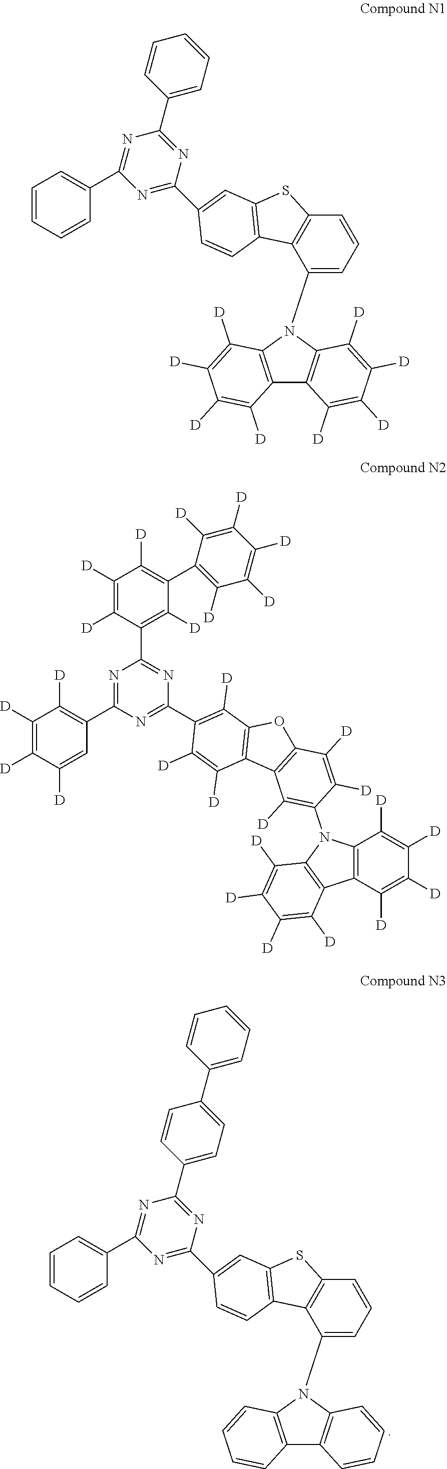 [SMILES: [2H]c1c([2H])c([2H])c2c(c1[2H])c1c([2H])c([2H])c([2H])c([2H])c1n2-c1cccc2sc3cc(-c4nc(-c5ccccc5)nc(-c5ccccc5)n4)ccc3c12 ; [2H]c1cc(-c2nc(-c3c([2H])c([2H])c([2H])c(-c4c([2H])c([2H])c([2H])c([2H])c4[2H])c3[2H])nc(-c3c([2H])c([2H])c4c(oc5c([2H])c([2H])c(-n6c7c([2H])c([2H])c([2H])c([2H])c7c7c([2H])c([2H])c([2H])c([2H])c76)c([2H])c54)c3[2H])n2)c([2H])c([2H])c1[2H] ; c1ccc(-c2ccc(-c3nc(-c4ccccc4)nc(-c4ccc5c(c4)sc4cccc(-n6c7ccccc7c7ccccc76)c45)n3)cc2)cc1]

The synthesis method of the above compound N1 includes follows:

### (1) Synthesis of Intermediate N1-1

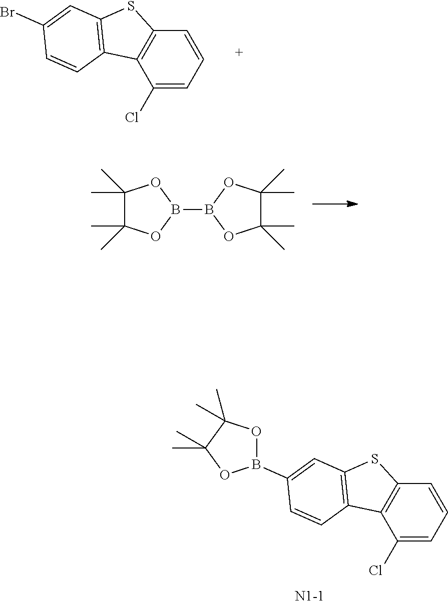

Under a nitrogen gas atmosphere, 7-Bromo-1-chlorodibenzothiophene (15.8 g, 53.2 mmol) and bis(pinacol)diboron (14.8 g, 58.4 mmol) are refluxed in 300 ml of 1,4-dioxane and stirred. Then, potassium acetate (7.6 g, 77.8 mmol) is added, and after being stirred sufficiently, bis(dibenzylideneacetone)palladium (0) (0.9 g, 1.6 mmol) and tricyclohexylphosphine (0.9 g, 3.2 mmol) are added. After 10 hours of reaction, being cooled to normal temperature, and the organic layer being separated by using chloroform and water, the organic layer is distilled. The obtained product is dissolved in chloroform again, after being washed twice with water, the organic layer is separated, then after anhydrous magnesium sulfate being added, being stirred and filtered, the filtrate is distilled under reduced pressure. The concentrated compound is purified by silica gel column chromatography, thus 14.2 g of intermediate N1-1 with a yield of 78% is produced.

### (2) Synthesis of Intermediate N1-2

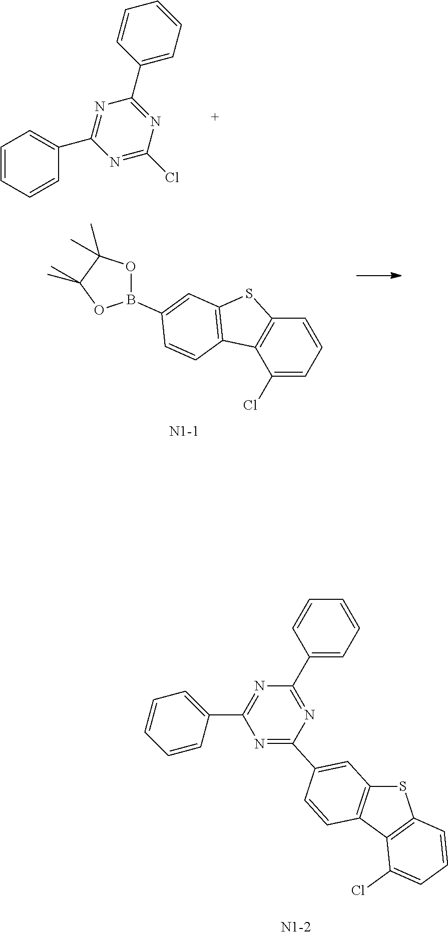 [SMILES: Clc1nc(-c2ccccc2)nc(-c2ccccc2)n1 ; CC1(C)OB(c2ccc3c(c2)sc2cccc(Cl)c23)OC1(C)C ; Clc1cccc2sc3cc(-c4nc(-c5ccccc5)nc(-c5ccccc5)n4)ccc3c12]

Under a nitrogen gas atmosphere, compound N1-1 (14.2 g, 43.2 mmol) and 2-chloro-4,6-diphenyl-1,3,5-triazine (13.0 g, 48.7 mmol) are added to 300 ml of tetrahydrofuran (THF), which is then stirred and refluxed. Then, potassium carbonate (24.8 g, 179.7 mmol) is dissolved in 75 ml of water, after being stirred sufficiently, tetrakis(triphenylphosphine)palladium (0) (1.6 g, 1.4 mmol) is added. After 8.5 hours of reaction, being cooled to normal temperature, the organic layer and water being separated, the organic layer is distilled. The obtained product is dissolved in chloroform again, after being washed twice with water, the organic layer is separated, then after anhydrous magnesium sulfate being added, being stirred and filtered, the filtrate is distilled under reduced pressure. The concentrated compound is purified by silica gel column chromatography, thus 15.3 g of intermediate N1-2 with a yield of 82% is produced.

### (3) Synthesis of Compound N1

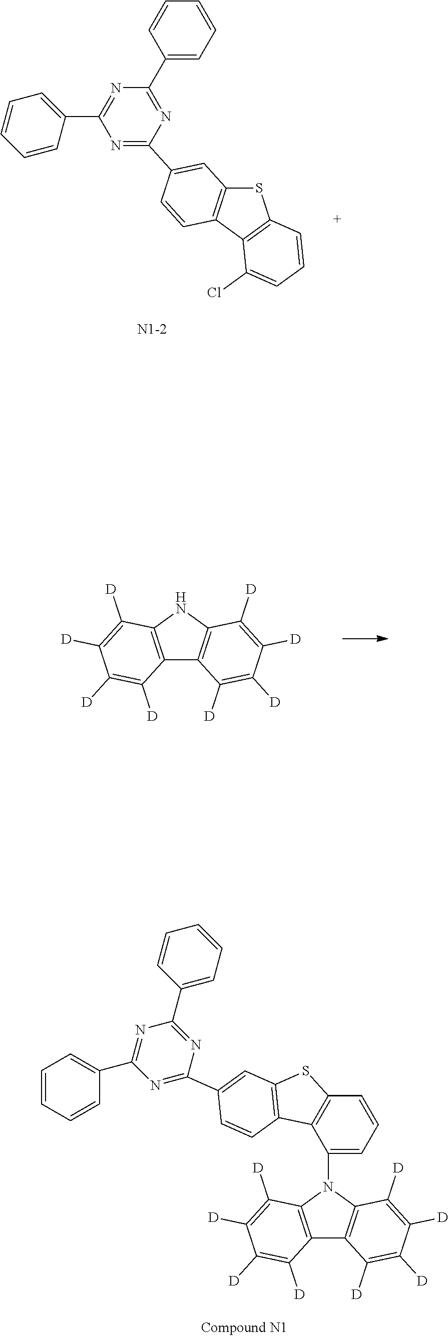 [SMILES: Clc1cccc2sc3cc(-c4nc(-c5ccccc5)nc(-c5ccccc5)n4)ccc3c12 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1cccc2sc3cc(-c4nc(-c5ccccc5)nc(-c5ccccc5)n4)ccc3c12]

Under a nitrogen gas atmosphere, compound N1-2 (15.0 g, 36.7 mmol) and deuterated carbazole (12.4 g, 39 mmol) are added to 300 ml of toluene, which is then stirred and refluxed. Then, sodium tert-butoxide (4.9 g, 50.9 mmol) and bis(tri-tert-butylphosphine)palladium (0) (0.5 g, 1.0 mmol) are added. After 7.5 hours of reaction, being cooled to normal temperature, and the organic layer being separated by using chloroform and water, the organic layer is distilled. The obtained product is dissolved in chloroform again, after being washed twice with water, the organic layer is separated, then after anhydrous magnesium sulfate being added, being stirred and filtered, the filtrate is distilled under reduced pressure. The concentrated compound is purified by silica gel column chromatography, thus 9.4 g of intermediate N1 with a yield of 48% is produced.

The dopant material is a phosphorescent material. The phosphorescent material may be a phosphorescent electroluminescent material, emitting light that can be green, but the present disclosure does not specifically limit this. The orientation value of the dopant material in the light emitting layer may be greater than or equal to −0.45. The orientation value of the dopant material in the light emitting layer may be less than or equal to −0.15. The aforementioned dopant material includes a compound having a structural formula as shown in Formula 1:

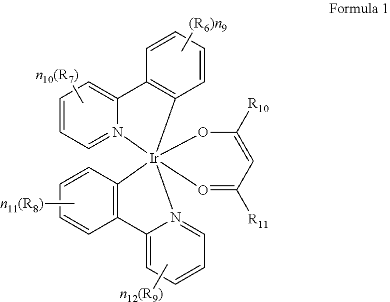

where, R₆-R₉ are each independently selected from a group consisting of hydrogen and deuterium; R₆-R₉ are further each independently selected from a group consisting of methyl, ethyl, propyl, cyclohexyl, and phenyl that are deuterium-substituted or non-deuterium-substituted. R₁₀ and R₁₁ are each independently selected from a group consisting of deuterium-substituted methyl, deuterium-substituted ethyl, and deuterium-substituted propyl or non-deuterium-substituted. The aforementioned n₉-n₁₂ are each independently 0, 1, 2, 3, or 4. For example, R₆-R₁₁ are each independently

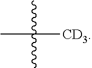 [SMILES: *C([2H])([2H])[2H]]

In the complex having a structural formula as shown in Formula 1,

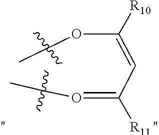

is an auxiliary ligand, while

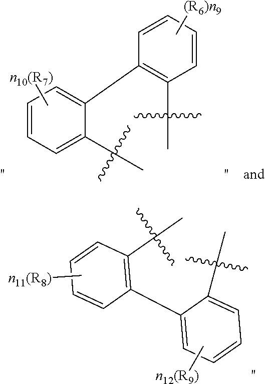

are main ligands. For example, R₁₀ and R₁₁ are each independently selected from a group consisting of deuterium-substituted methyl, deuterium-substituted ethyl, and deuterium-substituted propyl, the ratio of the quantity of deuterium atoms in R₁₀ and R₁₁ to the quantity of deuterium atoms in the compound having the structural formula as shown in Formula 1 is greater than or equal to 1/11; that is to say, the ratio of the quantity of deuterium atoms in the auxiliary ligand to the quantity of deuterium atoms in the main ligand is greater than or equal to 1/10; the ratio of the quantity of deuterium atoms in R₁₀ and R₁₁ to the quantity of deuterium atoms in the compound having the structural formula as shown in Formula 1 is less than or equal to 1/3, that is to say, the ratio of the quantity of deuterium atoms in the auxiliary ligand to the quantity of deuterium atoms in the main ligand is greater than or equal to 1/2. In addition, the quantity of deuterium atoms in the compound having the structural formula as shown in Formula 1 is less than or equal to 32; the quantity of deuterium atoms in the compound having the structural formula as shown in Formula 1 is greater than or equal to 3.

For example, the aforementioned dopant material includes a compound having any one of the following structural formulas:

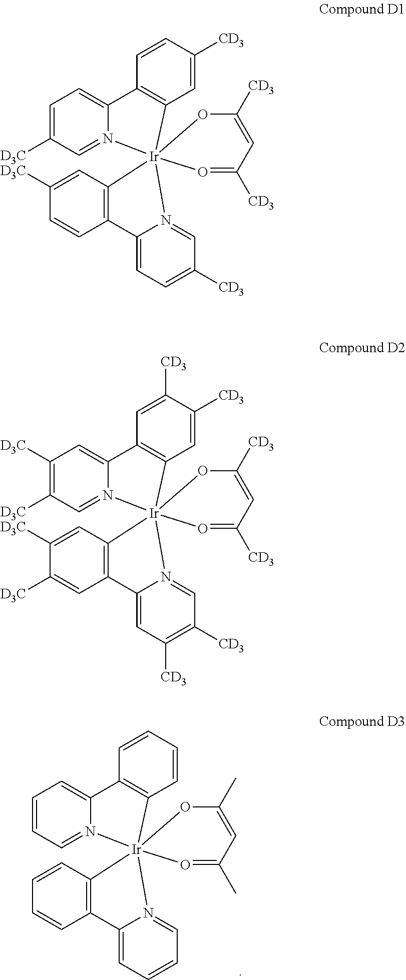

The synthesis method of the above compound D1 includes follows:

### (1) Synthesis of Intermediate D1-1

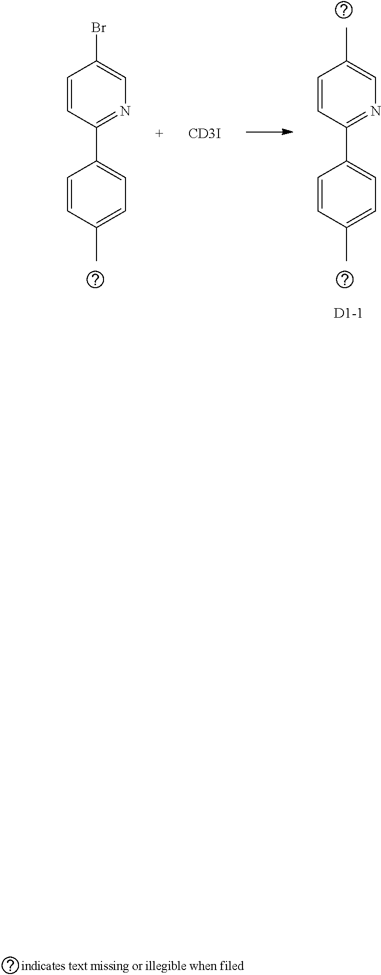

A 500 ml round-bottomed flask equipped with a dropping funnel, a nitrogen gas inlet and a stopper is heated and dried with a hot air blower under vacuum. 5-Bromo-2-(4-bromophenyl)pyridine (15.6 g, 50.0 mmol) and 100 mL THF were added to the flask. the solution is cooled under nitrogen gas in a dry ice/acetone bath, and methyl iodide-d3 (CD3I) (6 mL, 96.5 mmol) is added dropwise. The solution is cooled and stirred for 1 hour, warmed to room temperature, and overnight, it is diluted with water and extracted twice with ethyl acetate. The organic layer is dried with magnesium sulfate, filtered, and evaporated. The crude material is purified twice by column chromatography with 2% ethyl acetate/hexane elution. 6.8 g of 2-(4-methyl-d3-phenyl)-5-methyl-d3-pyridine (74%) is obtained, i.e., intermediate D1-1 is obtained.

### (2) Synthesis of Intermediate D1-2

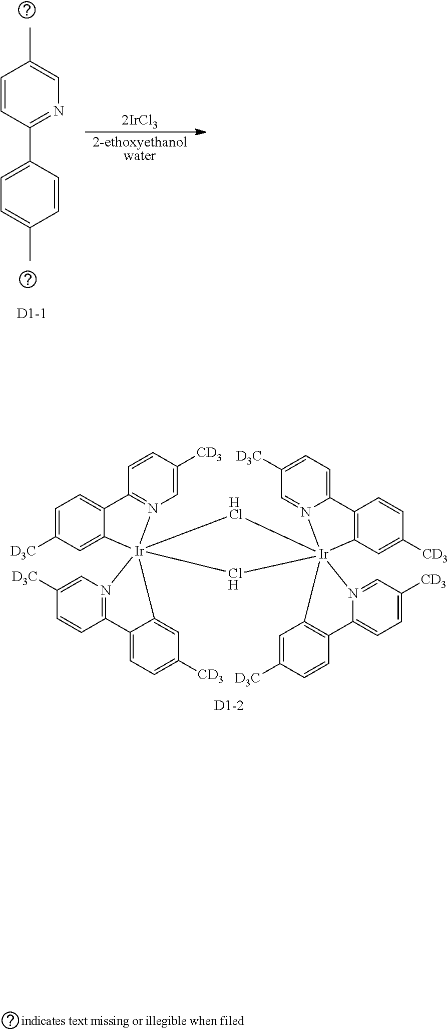

A mixture of intermediate D1-1 (1.86 g, 9.8 mmol), iridium chloride (1.69 g, 4.6 mmol), and 35 mL of 2-ethoxyethanol is heated and refluxed overnight under nitrogen gas. The mixture is cooled to room temperature and the solid product is filtered out. The solids are washed with methanol and ethane and air-dried in a fume hood. 1.28 g of dimer product (49%) i.e., intermediate D1-2 is obtained.

### (3) Synthesis of Intermediate D1-3

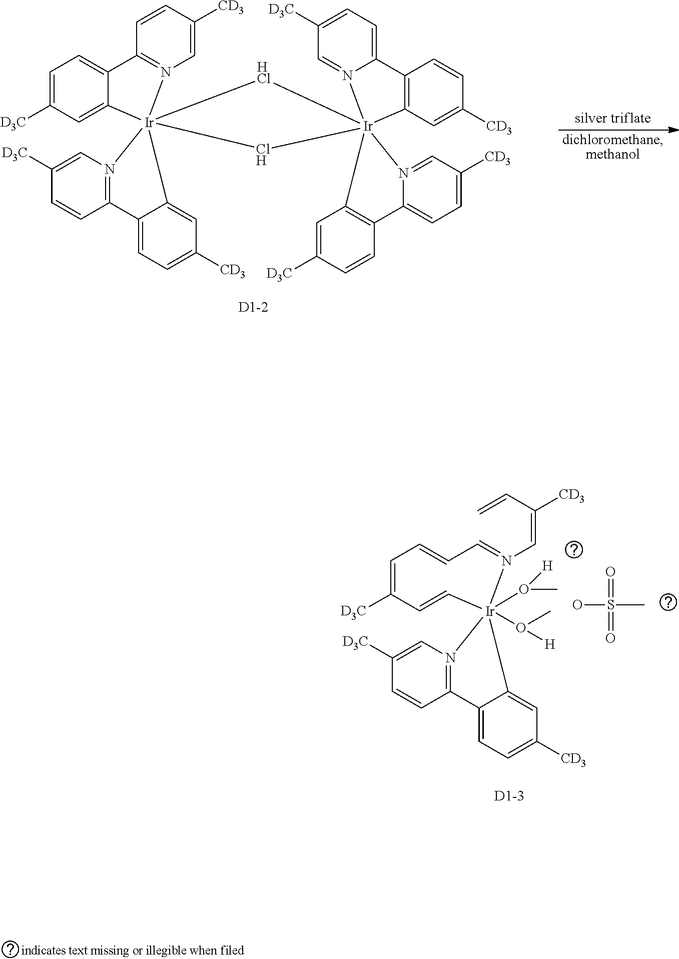

A mixture of dimer (1.28 g, 1.06 mmol) and 125 mL of dichloromethane is formed in a 250 mL round-bottomed flask. Silver triflate (0.51 g, 2.00 mmol) in 10 mL of methanol is added to the mixture. The substances of the flask are stirred at normal temperature overnight under nitrogen gas. The mixture is filtered through a pad of C (Celite) salt and the C salt is rinsed dichloromethane. The filtrate is evaporated to yield a solid product with (trifluoromethanesulfonate complex), i.e., intermediate D1-3. D1-3 is dried under high vacuum. 1 g D1-3 (70%) is obtained for the next reaction.

### (4) Synthesis of Compound D1

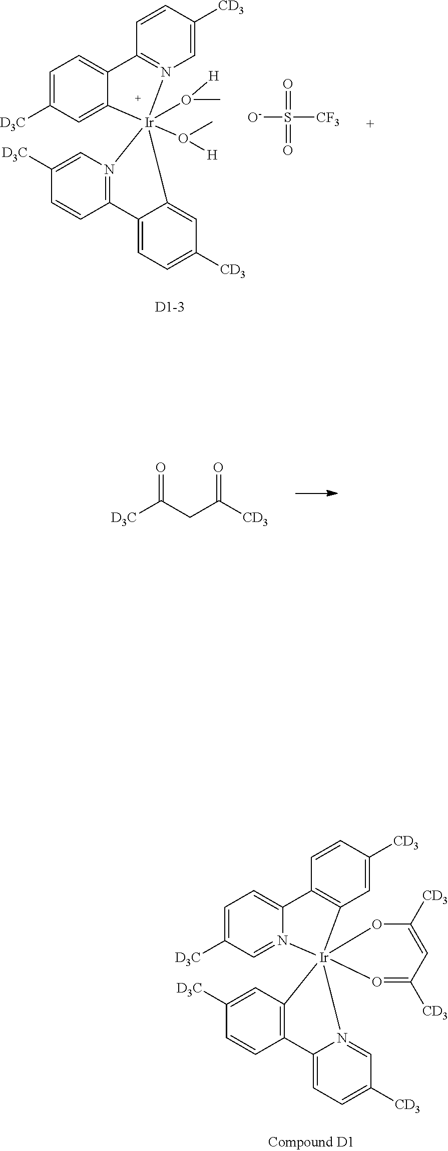

D1-3 (1.4 g), 1,3-dimethyl-d3propane-1,3-dione (1.5 g), and 50 mL ethanol are mixed, and heated and refluxed overnight under nitrogen gas, then the precipitate is filtered. The crude material is purified by column chromatography with 50% dichloromethane/hexane elution, then 1.2 g of compound D1 is obtained.

The aforementioned electron barrier layer may include a compound having a structural formula as shown in Formula 4:

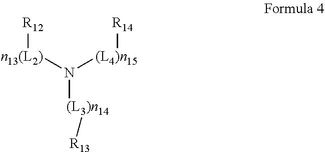

R₁₂, R₁₃, and R₁₄ are each independently selected from a group consisting of benzene, biphenyl, naphthalene, dibenzofuran, dibenzothiophene, dimethylfluorene, diphenylfluorene, spirofluorene, carbazole, and adamantine that are deuterium-substituted or non-deuterium-substituted. Further, R₁₂, R₁₃, and R₁₄ are each independently selected from a group consisting of

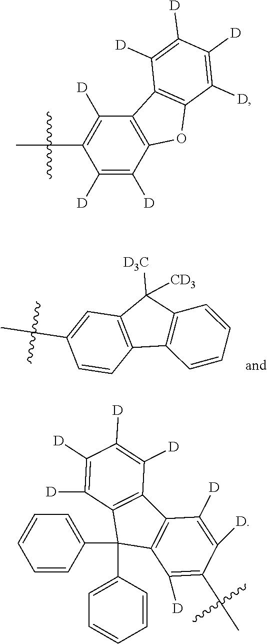

The aforementioned R₁₂, R₁₃, and R₁₄ may be the same as each other, or may be different from each other. L₂, L₃, and L₄ are each independently selected from a group consisting of benzene, biphenyl, naphthalene, dibenzofuran, dibenzothiophene, dimethylfluorene, diphenylfluorene, spirofluorene, carbazole, and adamantine that are deuterium-substituted or non-deuterium-substituted. n₁₃, n₁₄, and n₁₅ are each independently 0 or 1.

In addition, the quantity of deuterium atoms in the compound having the structural formula as shown in Formula 4 is less than or equal to 30. For the light emitting components of the present disclosure, the quantity of deuterium atoms in the hole type material, the electron type material, the dopant material, and the electron barrier layer is less than or equal to 108, i.e., the sum of the quantity of deuterium atoms in the hole type material, the quantity of deuterium atoms in the electron type material, the quantity of deuterium atoms in the dopant material, and the quantity of deuterium atoms in the electron barrier layer is less than or equal to 108; the quantity of deuterium atoms in the hole type material, the electron type material, the dopant material, and the electron barrier layer is greater than or equal to 4, i.e., the sum of the quantity of deuterium atoms in the hole type material, the quantity of deuterium atoms in the electron type material, the quantity of deuterium atoms in the dopant material, and the quantity of deuterium atoms in the electron barrier layer is greater than or equal to 4.

For example, the aforementioned electron barrier layer includes a compound having any one of the following structural formulas:

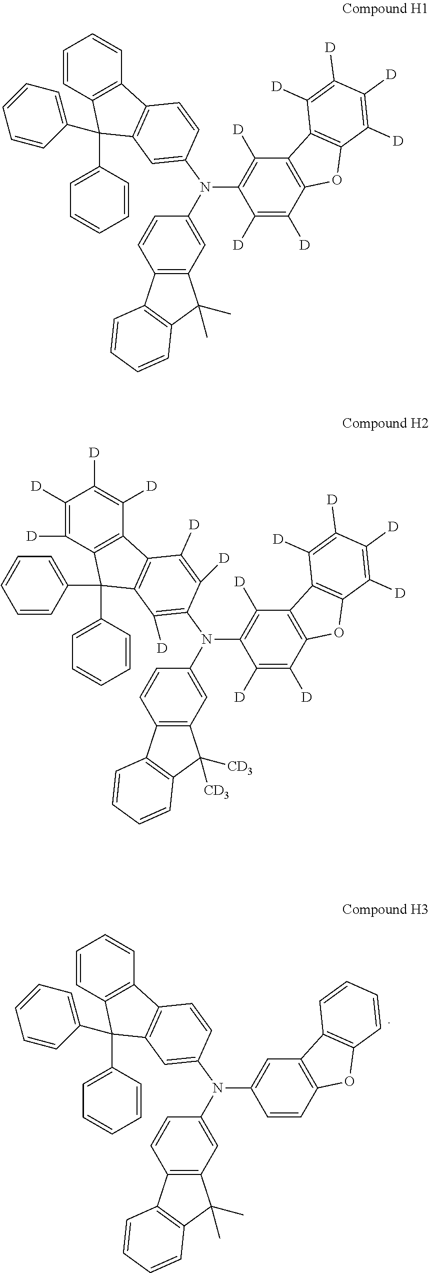 [SMILES: [2H]c1c([2H])c([2H])c2c(oc3c([2H])c([2H])c(N(c4ccc5c(c4)C(C)(C)c4ccccc4-5)c4ccc5c(c4)C(c4ccccc4)(c4ccccc4)c4ccccc4-5)c([2H])c32)c1[2H] ; [2H]c1c([2H])c([2H])c2c(c1[2H])-c1c([2H])c([2H])c(N(c3ccc4c(c3)C(C([2H])([2H])[2H])(C([2H])([2H])[2H])c3ccccc3-4)c3c([2H])c([2H])c4oc5c([2H])c([2H])c([2H])c([2H])c5c4c3[2H])c([2H])c1C2(c1ccccc1)c1ccccc1 ; CC1(C)c2ccccc2-c2ccc(N(c3ccc4c(c3)C(c3ccccc3)(c3ccccc3)c3ccccc3-4)c3ccc4oc5ccccc5c4c3)cc21]

The synthesis method of the above compound H1 includes follows:

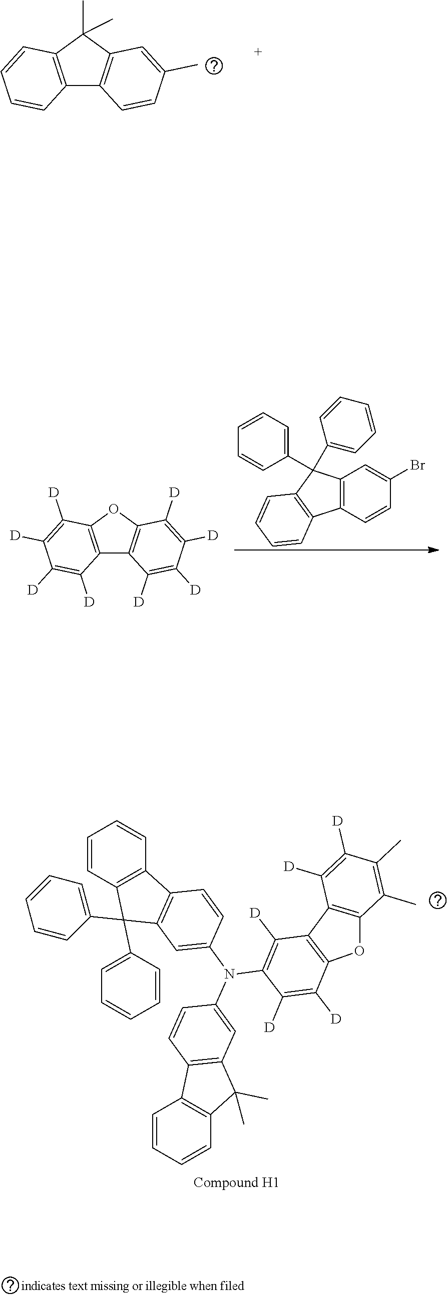

Under nitrogen gas protection, 86.5 mmol of 2-amino-9,9-dimethylfluorene, 86.5 mmol of 2-chlorodibenzofuran, 690 mL of toluene, and 259.6 mmol of sodium tert-butoxide are added into the reaction bottle, then it is stirred, and heated to 75° C.; 0.86 mmol of Pd2dba3 (CAS Number: 60748-47-2) and 1.73 mmol of s-PHOS are added slowly, after the addition is completed, the temperature is raised up to 110° C., reflux reaction is performed for 12 h, then it is cooled down to 75° C.; 84.6 mmol of 2-bromo-9,9-diphenylfluorene is added, the temperature is raised up to 105° C., reflux reaction is performed for 10 h; after the reaction is completed, it is cooled down, extracted with dichloromethane, and the organic phase is washed with water; it is dried, filtered and concentrated. A mixed solvent of methylene chloride and n-heptane is used for post-column recrystallization, and dried, the compound H1 is obtained, with a yield of 62%.

The light emitting component of the present disclosure may further include a hole injection layer 2 (HIL) and a hole transport layer 3 (HTL). The hole injection layer 2 may be between the anode 1 and the light emitting layer 5, and the hole transport layer 3 may be between the hole injection layer 2 and the light emitting layer 5. The aforementioned electron barrier layer 4 may be between the hole transport layer 3 and the light emitting layer 5. The material of the hole transport layer 3 may be selected from a group consisting of phthalocyanine derivatives, naphthalocyanine derivatives, porphyrin derivatives, biphenylamine-based triarylamines, styrylamine-based triarylamines, and diamine-based triarylamines. The material of the hole injection layer 2 may be selected from a group consisting of biphenylamine derivative, starburst aromatic amine compound, phthalocyanine derivative, and polyaza-triphenylene compound.

Further, the light emitting component of the present disclosure may further include an electron injection layer 8 (HIL), an electron transport layer 7 (ETL), and a hole barrier layer 6 (HBL). The electron injection layer 8 may be between the cathode 9 and the light emitting layer 5, the electron transport layer 7 may be between the electron injection layer 8 and the light emitting layer 5, and the hole barrier layer 6 may be between the electron transport layer 7 and the light emitting layer 5. The material of the electron transport layer 7 may be selected from a group consisting of benzimidazole derivatives, oxadiazole derivatives, and quinoxaline derivatives. The material of the electron injection layer 8 may be selected from a group consisting of alkali metal sulfides and alkali metal halides.

The following provides manufacturing embodiments of the light emitting component according to the present embodiment.

### Embodiment 1

The ITO (Indium Tin Oxide) substrate manufactured in advance is cleaned and dried, and the glass plate with ITO is used as an anode of the light emitting component; a hole injection layer, a hole transport layer, an electron barrier layer, a light emitting layer, a hole barrier layer, an electron transport layer, an electron injection layer, a cathode and a light capping layer (CPL) are sequentially evaporatively deposited on a side of the anode. The material of the hole injection layer may be compound M1 in Table 1. The material of the hole transport layer may be compound M2 in Table 1. The material of the electron barrier layer may be aforementioned compound H1. The material of the hole barrier layer may be compound M3 in Table 1. The material of the electron transport layer may include Liq (liquid) material and compound M4 in Table 1, and the rate ratio of Liq material to compound M4 during the deposition process is 1:1. The material of the electron injection layer may be the lanthanide metal Yb. The material of the CPL may be compound M5 in Table 1. The cathode is an MgAg electrode. The light emitting layer has a thickness of 40 nm, the hole type material in the host material of the light emitting layer is the aforementioned compound P1, the electron type material is the aforementioned compound N1, and the dopant material is the aforementioned compound D1, and the mass ratio of the host material to the dopant material is 9/1, and in the host material, the mass ratio of the hole type material to the electron type material is 3/2.

TABLE 1

| | |
|---|---|
| 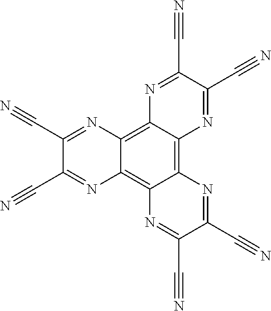 [SMILES: N#Cc1nc2c3nc(C#N)c(C#N)nc3c3nc(C#N)c(C#N)nc3c2nc1C#N] | Compound M1 |
| 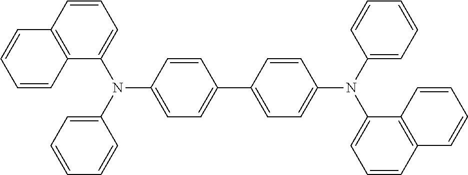 [SMILES: c1ccc(N(c2ccc(-c3ccc(N(c4ccccc4)c4cccc5ccccc45)cc3)cc2)c2cccc3ccccc23)cc1] | Compound M2 |
| 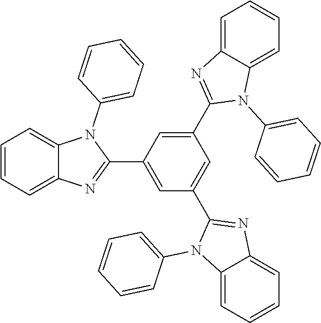 [SMILES: c1ccc(-n2c(-c3cc(-c4nc5ccccc5n4-c4ccccc4)cc(-c4nc5ccccc5n4-c4ccccc4)c3)nc3ccccc32)cc1] | Compound M3 |
| 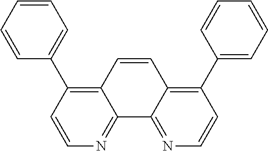 [SMILES: c1ccc(-c2ccnc3c2ccc2c(-c4ccccc4)ccnc23)cc1] | Compound M4 |
| 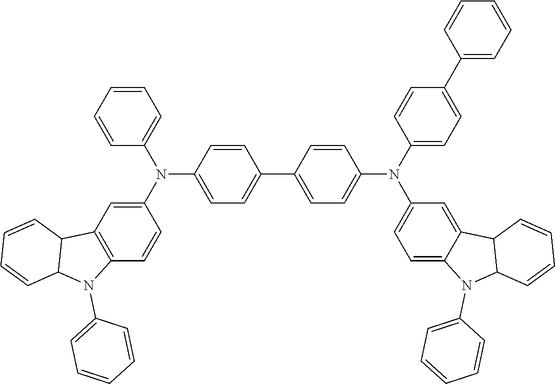 [SMILES: C1=CC2c3cc(N(c4ccccc4)c4ccc(-c5ccc(N(c6ccc(-c7ccccc7)cc6)c6ccc7c(c6)C6C=CC=CC6N7c6ccccc6)cc5)cc4)ccc3N(c3ccccc3)C2C=C1] | Compound M5 |

### Embodiment 2

The light-emitting component is manufactured by the same manufacturing method as in embodiment 1, with the difference that, the hole type material is the aforementioned compound P2, the electron type material is the aforementioned compound N2, and the dopant material is the aforementioned compound D2.

### Embodiment 3

The light-emitting component is manufactured by the same manufacturing method as in embodiment 1, with the difference that, the hole type material is the aforementioned compound P3.

### Embodiment 4

The light-emitting component is manufactured by the same manufacturing method as in embodiment 1, with the difference that, the electron type material is the aforementioned compound N3, and the material of the electron barrier layer is the aforementioned compound H2.

### Embodiment 5

The light-emitting component is manufactured by the same manufacturing method as in embodiment 1, with the difference that, the hole type material is the aforementioned compound P3, the electron type material is the aforementioned compound N3, and the material of the electron barrier layer is the aforementioned compound H2.

### Comparative Example 1

The light-emitting component is manufactured by the same manufacturing method as in embodiment 1, with the difference that, the hole type material is the aforementioned compound P3, the electron type material is the aforementioned compound N3, the dopant material is the aforementioned compound D3, and the material of the electron barrier layer is the aforementioned compound H3.

The physical property data of the aforementioned compound P1, compound P2, compound P3, compound N1, compound N2, compound N3, compound D1, compound D2, compound D3, compound H1, compound H2, and compound H3 are shown in Table 2:

TABLE 2

| | HOMO/ | LUMO/ | | Quantity | Orientation |
|---|---|---|---|---|---|
| | eV | eV | T1 | of D | S |
| Compound P1 | 5.41 | 2.03 | 2.48 | 10 | — |
| Compound P2 | 5.44 | 2.08 | 2.45 | 32 | — |
| Compound P3 | 5.45 | 2.11 | 2.51 | 0 | — |
| Compound N1 | 5.76 | 2.44 | 2.41 | 8 | — |
| Compound N2 | 2.81 | 2.46 | 2.38 | 27 | — |
| Compound N3 | 5.88 | 2.41 | 2.40 | 0 | — |
| Compound H1 | 5.45 | 2.36 | 2.51 | 7 | — |
| Compound H2 | 5.51 | 2.42 | 2.52 | 20 | — |
| Compound H3 | 5.54 | 2.44 | 2.52 | 0 | — |
| Compound D1 | 5.08 | 2.59 | 2.33 | 18 | −0.28 |
| Compound D2 | 5.01 | 2.62 | 2.32 | 30 | −0.36 |
| Compound D3 | 5.05 | 2.66 | 2.33 | 0 | −0.14 |

The present disclosure performs performance tests on the manufactured light emitting components, and the results are shown in Table 3.

TABLE 3

| | light | | | | | |
|---|---|---|---|---|---|---|
| | emitting | | | | | |
| | layer | | | | | Lifespan |
| | material | Voltage/V | Cd/A | CIE x | CIE y | (LT95) |
| Embodiment 1 | P1:N1:D1 | 100% | 100% | 0.245 | 0.722 | 100% |
| Embodiment 2 | P2:N2:D2 | 101% | 108% | 0.244 | 0.721 | 126% |
| Embodiment 3 | P3:N1:D1 | 98% | 98% | 0.244 | 0.722 | 88% |
| Embodiment 4 | P1:N3:D1 | 99% | 97% | 0.245 | 0.720 | 85% |
| Embodiment 5 | P3:N3:D1 | 100% | 97% | 0.242 | 0.719 | 74% |
| Comparative | P3:N3:D3 | 103% | 82% | 0.243 | 0.722 | 62% |
| example 1 | | | | | | |

In Table 3, the data of Embodiment 1 is taken as a reference and setting the voltage, efficiency, and lifespan data to 100%, the lifespans of the light emitting components in embodiments 1-5 have all shown improvement compared to the light emitting component of comparative example 1.

The above embodiments are some embodiments of the present disclosure, and do not limit the present disclosure in any form. Although the present disclosure has been disclosed as the above with some embodiments, it is not intended to limit the present disclosure. Anyone who is familiar with this technology, within the scope of not departing from the technical solution of the present disclosure, can use the technical contents disclosed above to make some changes or modifications to equivalent embodiments of equivalent changes. However, within the technical contents of the present disclosure, any simple alterations, equal changes and modifications made to the above embodiments based on the technical nature of the present disclosure should fall within the protection scope of the present disclosure.

1. A light emitting component, comprising:
an anode, an electron barrier layer, a light emitting layer and a cathode that are stacked sequentially;
wherein the light emitting layer comprises a host material and a dopant material, the host material comprises a hole type material and an electron type material; wherein an electron transport rate in the light emitting layer is greater than a hole transport rate in the light emitting layer;
wherein the hole type material, the electron type material, the dopant material, the electron barrier layer or any combination thereof comprises a deuterium-substituted compound;
wherein the dopant material comprises a compound having a structural formula as shown in Formula 1: 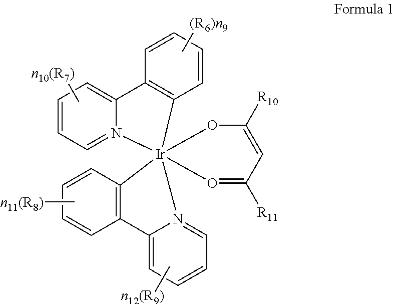
wherein R₆-R₉ are each independently selected from a group consisting of hydrogen and deuterium; R₆-R₉ are further each independently selected from a group consisting of methyl, ethyl, propyl, cyclohexyl, and phenyl that are deuterium-substituted or non-deuterium-substituted;
wherein n₉-n₁₂ are each 0, 1, 2, 3, or 4;
wherein R₁₀ and R₁₁ are each selected from a group consisting of deuterium-substituted methyl, deuterium-substituted ethyl, and deuterium-substituted propyl or non-deuterium-substituted.

2. The light emitting component according to claim 1, wherein the hole type material comprises a compound having a structural formula as shown in Formula 2: 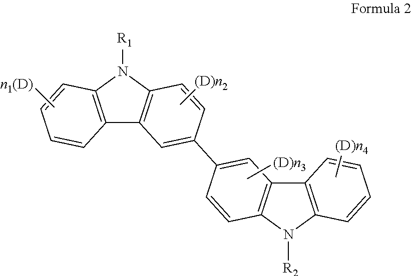
wherein R₁ and R₂ are each selected from a group consisting of benzene, biphenyl, terphenyl, naphthalene, dibenzofuran, dibenzothiophene, dimethylfluorene, and diphenylfluorene that are deuterium-substituted or non-deuterium-substituted; and
wherein n₁ and n₄ are each 0, 1, 2, 3, or 4; wherein n₂ and n₃ are each 0, 1, 2, or 3.

3. The light emitting component according to claim 2, wherein R₁ and R₂ are each selected from a group consisting of 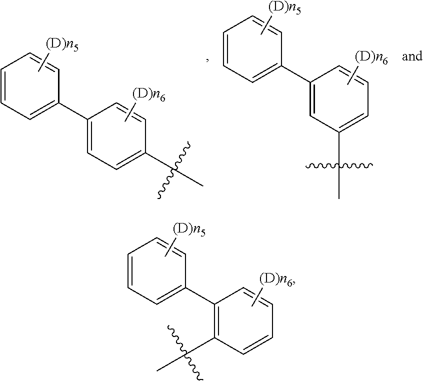
wherein n₅ is 0, 1, 2, 3, 4, or 5; n₆ is 0, 1, 2, 3, or 4.

4. The light emitting component according to claim 3, wherein the hole type material comprises a compound having any one of following structural formulas:

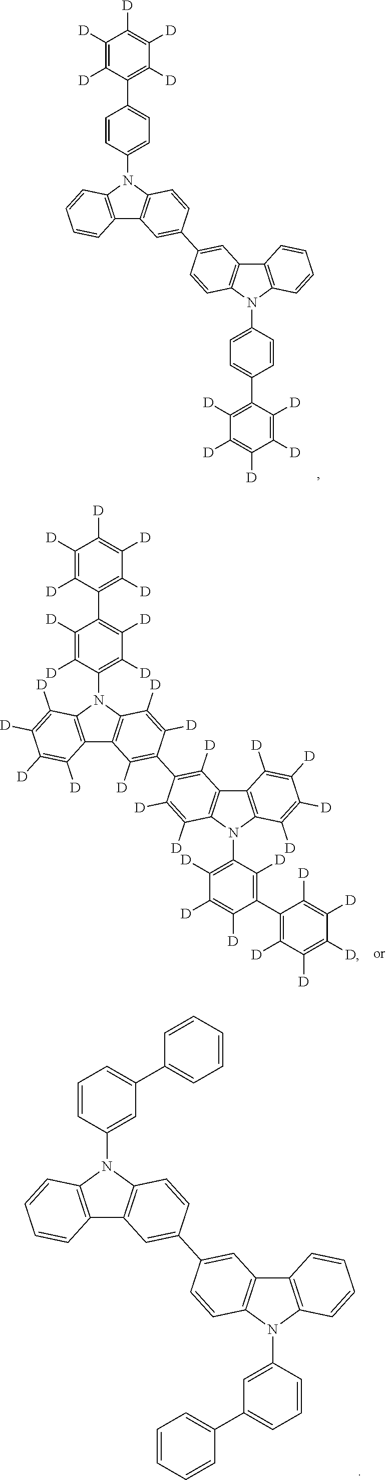

5. The light emitting component according to claim 2, wherein a quantity of deuterium atoms in the compound having the structural formula as shown in Formula 2 is less than or equal to 32.

6. The light emitting component according to claim 1, wherein the electron type material comprises a compound having a structural formula as shown in Formula 3: 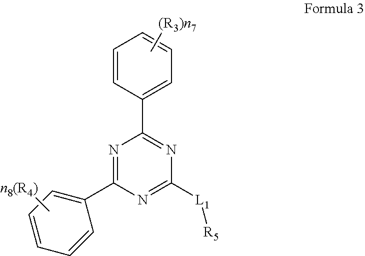
wherein R₃ and R₄ are each selected from a group consisting of hydrogen and deuterium, and R₃ and R₄ are further each selected from a group consisting of benzene, biphenyl, naphthalene, dibenzofuran, and dibenzothiophene that are deuterium-substituted or non-deuterium-substituted;
wherein n₇ and n₈ are each 0, 1, 2, 3, 4, or 5; and
wherein R₅ and L₁ are each selected from a group consisting of benzene, biphenyl, naphthalene, dibenzofuran, dibenzothiophene, and carbazole that are deuterium-substituted or non-deuterium-substituted.

7. The light emitting component according to claim 6, wherein R₃ and R₄ are each 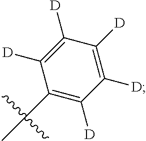
and/or
wherein R₅ is 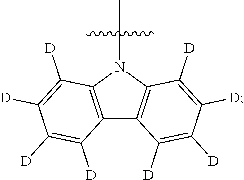
and/or
wherein L₁ is

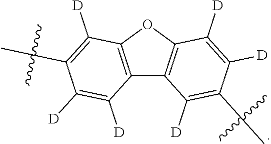 [SMILES: *c1c([2H])c([2H])c2c(oc3c([2H])c([2H])c(*)c([2H])c32)c1[2H]]

8.-9. (canceled)

10. The light emitting component according to claim 6, wherein the electron type material comprises a compound having any one of following structural formulas:

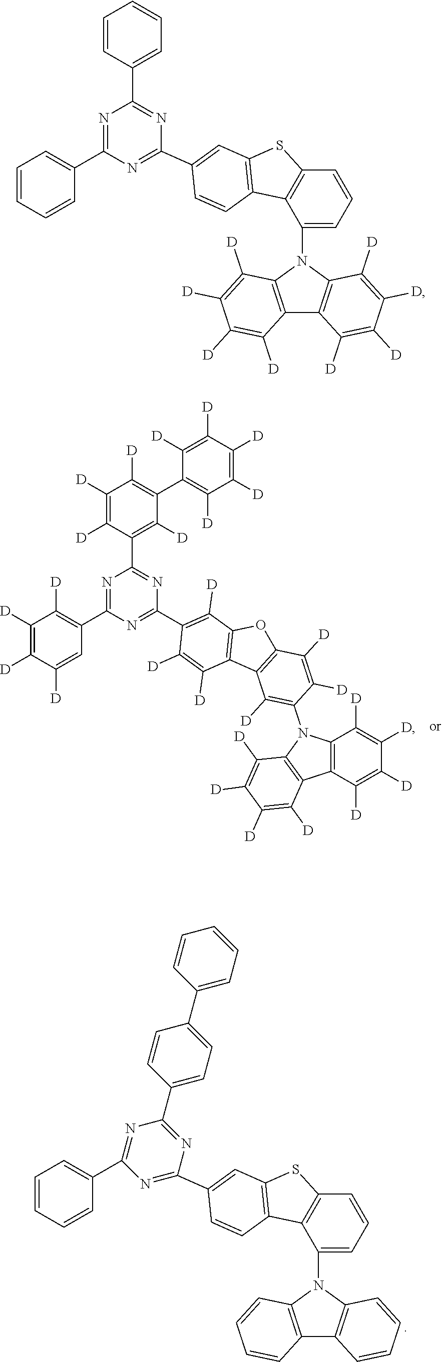

11. The light emitting component according to claim 6, wherein a quantity of deuterium atoms in the compound having the structural formula as shown in Formula 3 is less than or equal to 38.

12. The light emitting component according to claim 1, wherein R₆-R₁₁ are each

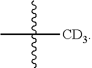 [SMILES: *C([2H])([2H])[2H]]

13. The light emitting component according to claim 1, wherein the dopant material comprises a compound having any one of following structural formulas:

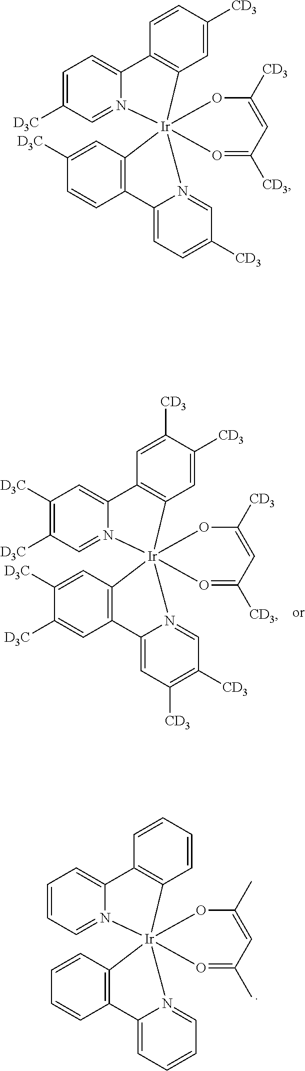

14. The light emitting component according to claim 1, wherein a quantity of deuterium atoms in the compound having the structural formula as shown in Formula 1 is less than or equal to 32; and/or
the quantity of deuterium atoms in the compound having the structural formula as shown in Formula 1 is greater than or equal to 3.

15. The light emitting component according to claim 1, wherein R₁₀ and R₁₁ are each selected from a group consisting of deuterium-substituted methyl, deuterium-substituted ethyl, and deuterium-substituted propyl;
wherein a ratio of a quantity of deuterium atoms in R₁₀ and R₁₁ to a quantity of deuterium atoms in the compound having the structural formula as shown in Formula 1 is greater than or equal to 1/11; and/or, the ratio of the quantity of deuterium atoms in R₁₀ and R₁₁ to the quantity of deuterium atoms in the compound having the structural formula as shown in Formula 1 is less than or equal to 1/3.

16. The light emitting component according to claim 1, wherein the dopant material is a phosphorescent material;
wherein an orientation value of the dopant material in the light emitting layer is greater than or equal to −0.45; and/or, the orientation value of the dopant material in the light emitting layer is less than or equal to −0.15.

17. The light emitting component according to claim 1, wherein the electron barrier layer comprises a compound having a structural formula as shown in Formula 4: 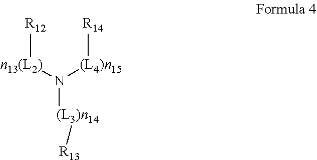
wherein R₁₂, R₁₃, R₁₄, L₂, L₃, and L₄ are each selected from a group consisting of benzene, biphenyl, naphthalene, dibenzofuran, dibenzothiophene, dimethylfluorene, diphenylfluorene, spirofluorene, carbazole, and adamantine that are deuterium-substituted or non-deuterium-substituted; and
wherein n₁₃, n₁₄, and n₁₅ are each 0 or 1.

18. The light emitting component according to claim 17, wherein R₁₂, R₁₃, and R₁₄ are each selected from a group consisting of

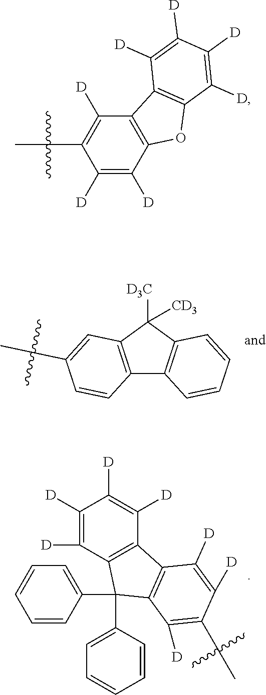

19. The light emitting component according to claim 17, wherein the electron barrier layer comprises a compound having any one of following structural formulas:

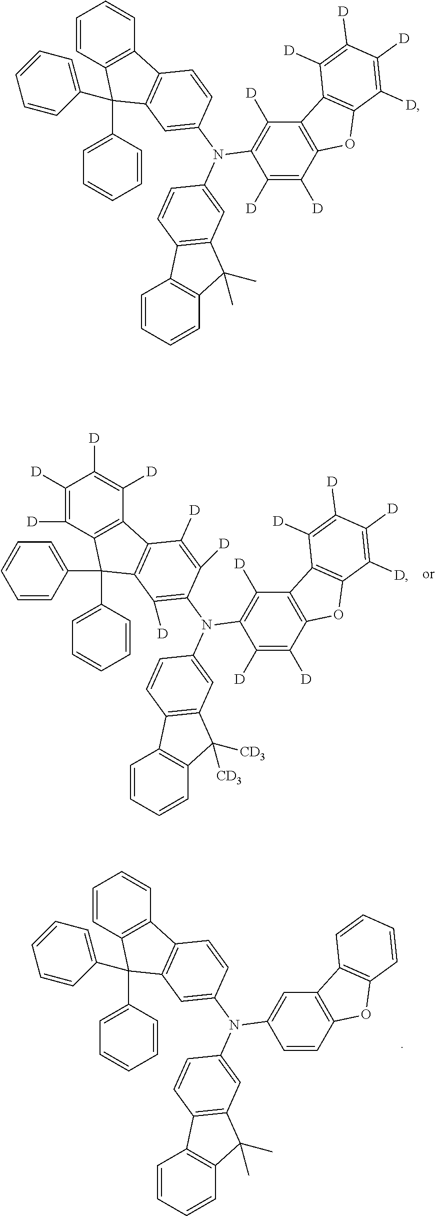

20. The light emitting component according to claim 17, wherein a quantity of deuterium atoms in the compound having the structural formula as shown in Formula 4 is less than or equal to 30.

21. The light emitting component according to claim 1, wherein a quantity of deuterium atoms in the hole type material, the electron type material, the dopant material, and the electron barrier layer is less than or equal to 108; and/or
a quantity of deuterium atoms in the hole type material, the electron type material, the dopant material, and the electron barrier layer is greater than or equal to 4.

22. A display device, comprising a light emitting component, wherein the light emitting component comprises:
an anode, an electron barrier layer, a light emitting layer and a cathode that are stacked sequentially;
wherein the light emitting layer comprises a host material and a dopant material, the host material comprises a hole type material and an electron type material; wherein an electron transport rate in the light emitting layer is greater than a hole transport rate in the light emitting layer;
wherein the hole type material, the electron type material, the dopant material, the electron barrier layer or any combination thereof comprises a deuterium-substituted compound;
wherein the dopant material comprises a compound having a structural formula as shown in Formula 1: 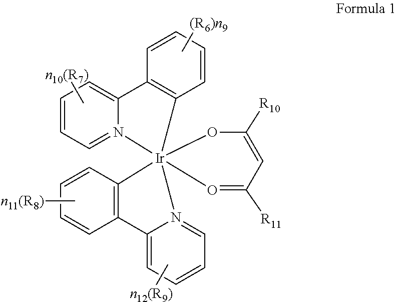
wherein R₆-R₉ are each selected from a group consisting of hydrogen and deuterium; R₆-R₉ are further each selected from a group consisting of methyl, ethyl, propyl, cyclohexyl, and phenyl that are deuterium-substituted or non-deuterium-substituted;
wherein n₉-n₁₂ are each 0, 1, 2, 3, or 4;
wherein R₁₀ and R₁₁ are each selected from a group consisting of deuterium-substituted methyl, deuterium-substituted ethyl, and deuterium-substituted propyl or non-deuterium-substituted.
